(19) United States
(12) Patent Application Publication
(10) Pub. No.: US 2026/0282936 A1
(43) Pub. Date: Sep. 17, 2026

(54) SEMICONDUCTOR DEVICE MANUFACTURING METHOD, AND SEMICONDUCTOR DEVICE

(71) Applicant: Kioxia Corporation, Tokyo (JP)

(72) Inventor: Ryoji YAMADA, Yokkaichi Mie (JP)

(73) Assignee: Kioxia Corporation, Tokyo (JP)

(21) Appl. No.: 19/237,928

(22) Filed: Jun. 13, 2025

(30) Foreign Application Priority Data
Mar. 14, 2025 (JP) 2025-041187

(51) Int. Cl. H01L 23/544

(52) U.S. Cl. CPC H10W 46/00; H10W 46/503

(57) ABSTRACT

In a semiconductor device manufacturing method according to one embodiment, in a first process, a device layer formed on a semiconductor substrate is irradiated with a laser beam having abrasion effect along a dicing line, and a plurality of grooves having a depth that does not reach the semiconductor substrate is formed in the device layer. In a second process, the dicing line is cut using a cutting blade. An interval between grooves closest to each other from among the plurality of grooves formed in the first process is smaller than a width of the cutting blade, and an interval between grooves located at both ends from among the plurality of grooves is greater than the width of the cutting blade.

### CROSS-REFERENCE TO RELATED APPLICATIONS

This application is based upon and claims the benefit of Japanese Patent Application No. 2025-041187, filed on Mar. 14, 2025; the entire contents of which are incorporated herein by reference.

### FIELD

Embodiments described herein relate generally to a semiconductor device manufacturing method, and a semiconductor device.

### BACKGROUND

Semiconductor chips are generated by separating individual chip areas of a semiconductor wafer provided with a plurality of chip areas from each other in a dicing process. A dicing line has been provided between chip areas.

When dicing the semiconductor wafer, a crack is generated near the dicing line in some cases. The extension of the crack to the chip area results in a defective semiconductor chip.

### BRIEF DESCRIPTION OF THE DRAWINGS

FIGS. 1A to 1C are schematic diagrams illustrating an example of a configuration of a semiconductor device according to an embodiment;

FIG. 2 is a top view illustrating an example of a configuration of a semiconductor wafer according to the embodiment;

FIGS. 3A and 3B are diagrams sequentially illustrating a flow of a semiconductor device manufacturing method according to the embodiment;

FIGS. 4A and 4B are diagrams sequentially illustrating the flow of the semiconductor device manufacturing method according to the embodiment;

FIGS. 5A and 5B are diagrams sequentially illustrating the flow of the semiconductor device manufacturing method according to the embodiment;

FIGS. 6A and 6B are diagrams sequentially illustrating the flow of the semiconductor device manufacturing method according to the embodiment;

FIGS. 7A and 7B are diagrams explaining the extension of a crack in a process of manufacturing the semiconductor device according to the embodiment; and

FIGS. 8A to 8C are diagrams explaining a semiconductor device manufacturing method in a comparative example.

### DETAILED DESCRIPTION

In a semiconductor device manufacturing method according to one embodiment, in a first process, a device layer formed on a semiconductor substrate is irradiated with a laser beam having abrasion effect along a dicing line of a semiconductor wafer to form a plurality of grooves having a depth that does not reach the semiconductor substrate in the device layer, the semiconductor wafer including chip areas that include circuit elements, and a kerf area that surrounds the chip areas, the dicing line being located in the kerf area, and being cut in singulating the chip areas. Then, in a second process, the dicing line is cut in a thickness direction of the semiconductor wafer using a cutting blade, and the chip areas are singulated. An interval between grooves closest to each other from among the plurality of grooves formed in the first process is smaller than a width of the cutting blade, and an interval between grooves located at both ends from among the plurality of grooves is greater than the width of the cutting blade.

Exemplary embodiments of a semiconductor device manufacturing method and a semiconductor device will be described below in detail with reference to the accompanying drawings. The present invention is not limited to these embodiments.

Herein, it is assumed that directions that correspond to an orientation of a plane of a word line WL described later are an X direction and a Y direction. The X direction and the Y direction are orthogonal to each other. It is also assumed that a direction that is orthogonal to the X direction and the Y direction is a Z direction. The Z direction is also a stacking direction of the word lines WL. It is also assumed that a direction pointed by an arrow of each axis is a positive direction, its opposite direction is a negative direction, a positive-direction side of a Z axis is an upper side, and a negative-direction side of the Z axis is a lower side.

### Configuration of Semiconductor Device

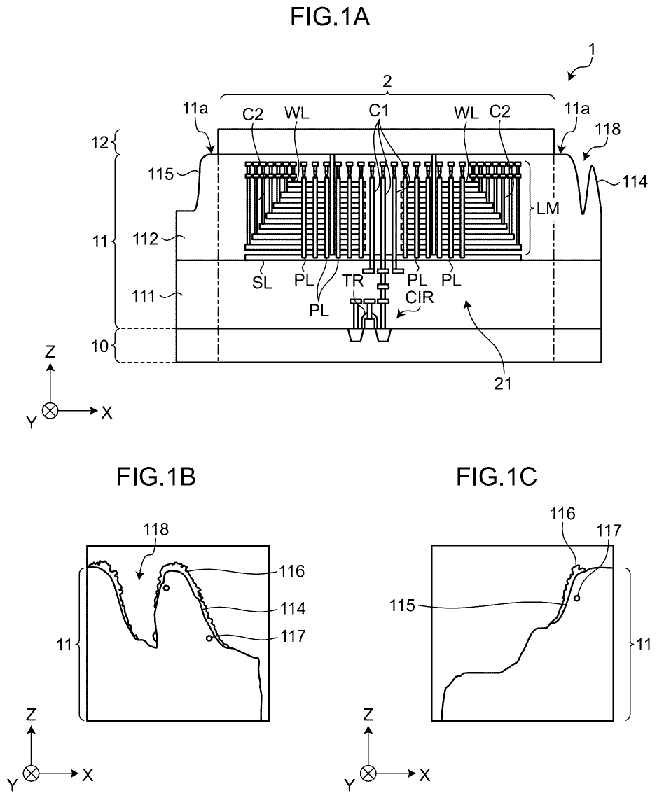

FIGS. 1A to 1C are schematic diagrams illustrating an example of a configuration of a semiconductor device 1 according to an embodiment. More specifically, FIG. 1A is a cross-sectional view in the X and Z directions of the semiconductor device 1, and FIGS. 1B and 1C are respectively enlarged cross-sectional views of edges in positive and negative directions of the X axis of the semiconductor device 1 of FIG. 1A. In FIG. 1A, hatching is omitted in consideration of easiness of viewing the drawing. Furthermore, in FIG. 1A, a portion of upper layer wiring is omitted.

As illustrated in FIG. 1A, the semiconductor device 1 includes a chip area 2 in an area near the center. In the chip area 2, a device layer 11 has been formed on a silicon substrate 10 serving as a semiconductor substrate, and a surface protective film 12 has been formed on the device layer 11. The device layer 11 has a thickness of 1 μm or more and less than 5 μm. Alternatively, the thickness may be 5 μm or more and less than 10 μm. The thickness may be greater, and may be 10 μm or more and less than 20 μm.

The device layer 11 includes, as material films, an insulation layer 111 and an insulation layer 112 in the order from the lower side. The insulation layer 111 and the insulation layer 112 are, for example, silicon oxide layers. However, a configuration example of the device layer 11 is not limited to the above. It is sufficient if the device layer 11 includes one or more material films. Furthermore, the surface protective film 12 may be omitted.

In the insulation layer 111, a peripheral circuit CIR is disposed. The peripheral circuit CIR includes a transistor TR, wiring, and the like, and contributes to an operation of a memory cell described later.

In the insulation layer 112, a source line SL is disposed. On the source line SL, a stacked body LM in which a plurality of word lines WL has been stacked has been formed. The insulation layer 112 covers the entirety of the stacked body LM.

The plurality of word lines WL that constitutes the stacked body LM has been stacked in such a way that a word line WL is separated from another word line WL with a not-illustrated insulation layer interposed therebetween. For the plurality of word lines WL, a plurality of pillars PL that penetrates the plurality of word lines WL in a stacking direction, that is, the Z direction, is disposed. In crossing portions of the pillars PL and the word lines WL, a plurality of memory cells is formed. Stated another way, the semiconductor device 1 is configured as a three-dimensional non-volatile memory in which a memory cell array has been three-dimensionally formed.

In the stacked body LM, a contact C1 that connects the peripheral circuit CIR located below the stacked body LM to the upper layer wiring or the like located above the stacked body LM is disposed. The peripheral circuit CIR may be disposed in a staircase-shaped area of the word lines WL described later. In this staircase-shaped area, the contact C1 that connects the upper layer wiring or the like to the peripheral circuit CIR may be disposed.

Ends of the plurality of word lines WL are configured in a staircase shape. At the end of each of the word lines WL, a contact C2 that connects the word line WL to the upper layer wiring or the like is disposed. By doing this, the word lines WL that are stacked in multiple layers can be individually drawn out.

The stacked body LM and the peripheral circuit CIR correspond to a circuit element 21. Stated another way, in the device layer 11 of the chip area 2, the circuit element 21 has been provided. The device layer 11 also spreads to an outside of the chip area 2.

In an outer periphery of the device layer 11, a groove 118 and inclined faces 114 and 115 that extend in an outer peripheral direction of the semiconductor device 1 have been formed.

For example, at an edge on a positive-direction side of the X axis of the semiconductor device 1, the groove 118 and the inclined face 114 have been formed.

The groove 118 has been formed by digging down the device layer 11 outside the chip area 2 up to a depth position that does not reach the silicon substrate 10. On a further positive-direction side of the X axis when viewed from the groove 118, the inclined face 114 has been formed. The inclined face 114 has been formed to descend from an upper face 11a of the device layer 11 toward the outside of the semiconductor device 1. However, it is sufficient if at least either the groove 118 or the inclined face 114 has been formed at the edge on the positive-direction side of the X axis of the semiconductor device 1.

On the other hand, for example, at an edge on a negative-direction side of the X axis of the semiconductor device 1, the inclined face 115 has been formed. The inclined face 115 has been formed to descend from the upper face 11a of the device layer 11 toward the outside of the semiconductor device 1. However, at the edge on the negative-direction side of the X axis of the semiconductor device 1, the groove 118 may be formed instead of the inclined face 115 or together with the inclined face 115.

The groove 118 and the inclined faces 114 and 115 have been formed by irradiating the device layer 11 with a laser beam. As illustrated in FIGS. 1B and 1C, on surfaces of the groove 118 and the inclined faces 114 and 115, a molten layer 116 has been formed. The surface of the device layer 11 is melted by the laser beam and is solidified to be formed into the molten layer 116.

Inside the molten layer 116 or near the molten layer 116, compressive stress has been generated due to the laser beam. Furthermore, a hole 117 has been formed in some cases. The hole 117 is formed in a process of melting and solidifying the device layer 11. The hole 117 has, for example, a roughly perfectly circular pinhole shape.

The semiconductor device 1 described above is formed by dicing the chip area 2 formed in the semiconductor wafer 100 into individual pieces.

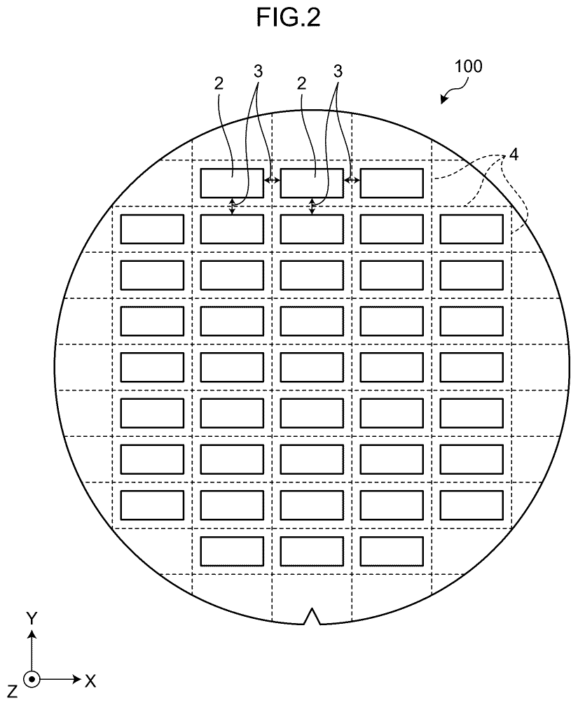

FIG. 2 is a top view illustrating an example of a configuration of the semiconductor wafer 100 according to the embodiment.

As illustrated in FIG. 2, in the semiconductor wafer 100, the plurality of chip areas 2 has been formed in matrix. In the example of FIG. 2, each of the chip areas 2 has a rectangular shape. Each of the chip areas 2 has been provided to be separated from an adjacent chip area 2.

In an area between chip areas 2 adjacent to each other, an area that may be sacrificed in dicing, namely, a kerf area 3, has been provided. In other words, the kerf area 3 has been provided to surround individual chip areas 2. In the kerf area 3, dicing lines 4 are disposed. The dicing lines 4 extend in the X direction and the Y direction. The semiconductor wafer 100 is cut in a thickness direction along the dicing lines 4 so that the chip areas 2 are singulated.

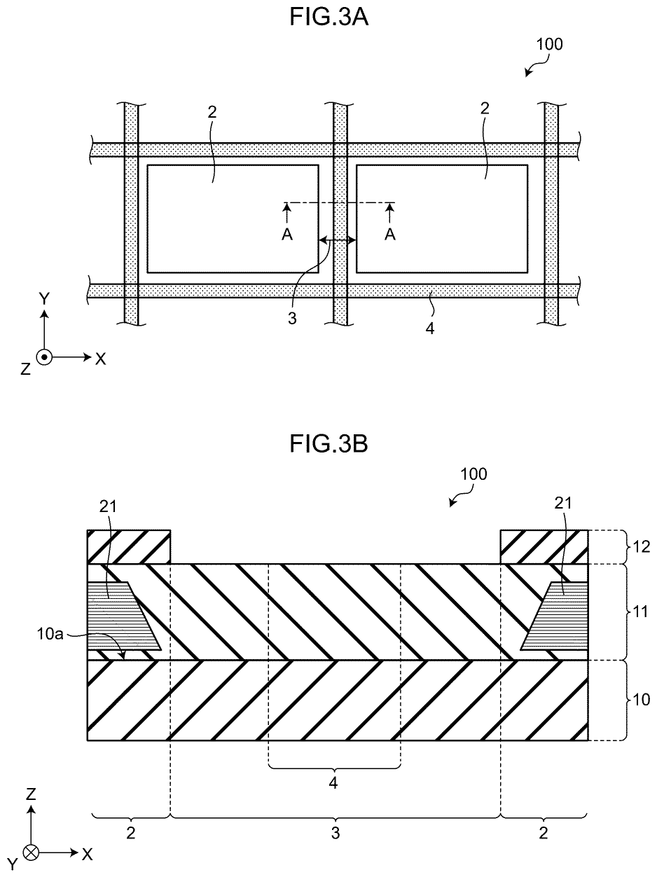

The semiconductor device 1 is generated as a result of dicing processing, as described above. Next, a flow of a method for manufacturing the semiconductor device 1 including the dicing processing described above will be described with reference to FIGS. 3A to 6B.

### Semiconductor Device Manufacturing Method

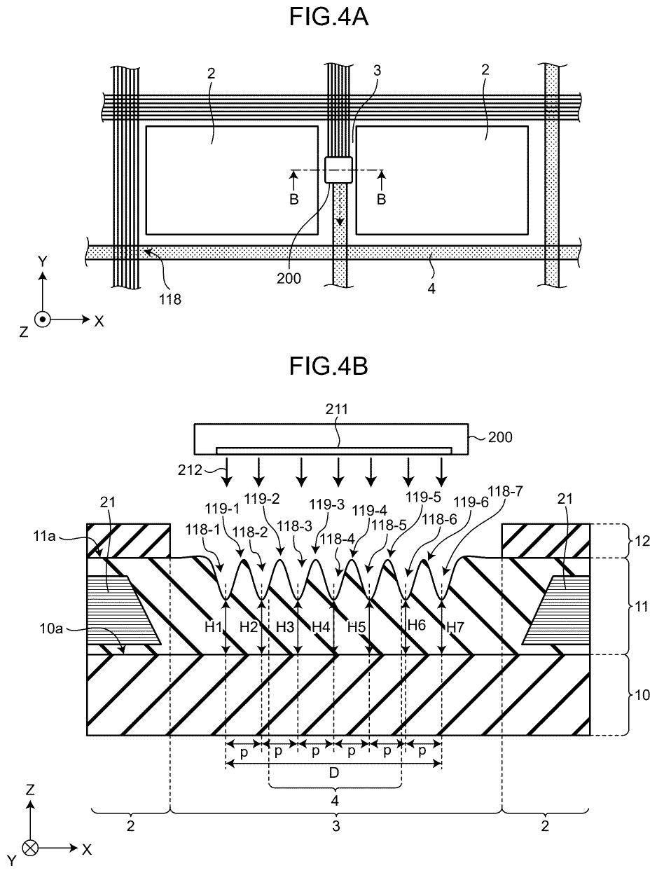

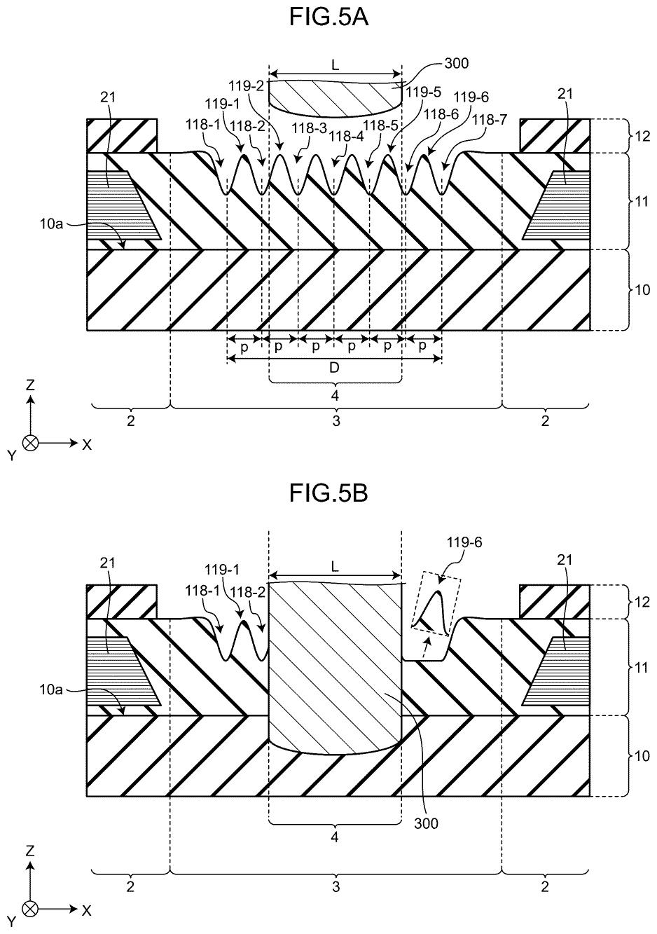

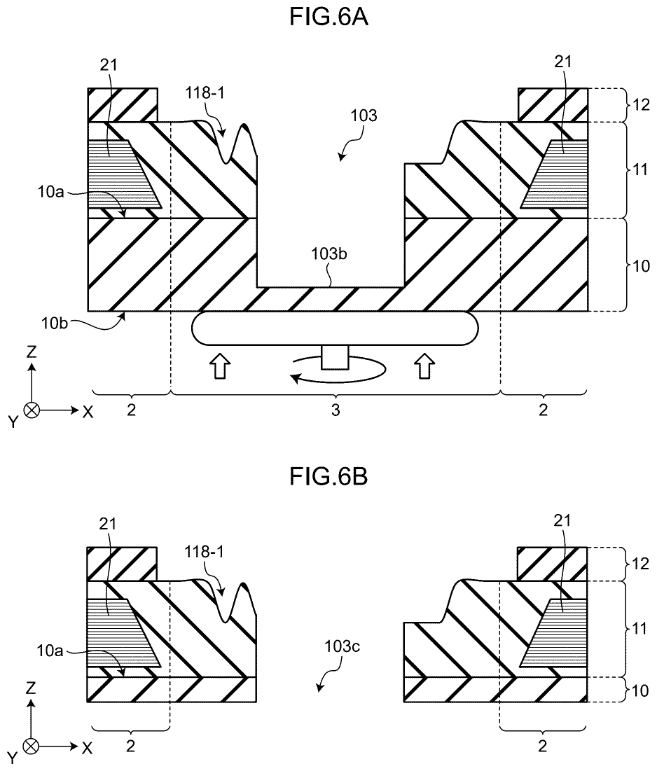

FIGS. 3A to 6B are diagrams sequentially illustrating a flow of a method for manufacturing the semiconductor device 1 according to the embodiment. More specifically, FIGS. 3A and 4A are enlarged top views of a portion of the semiconductor wafer 100. FIGS. 3B and 4B are cross-sectional views along line AA of FIG. 3A and line BB of FIG. 4A, respectively. Furthermore, FIGS. 5A to 6B are diagrams illustrating processing that follows the processing of FIG. 4B, and are cross-sectional views in a position that corresponds to line BB of FIG. 4A.

As illustrated in FIGS. 3A and 3B, the device layer 11 has been formed on the silicon substrate 10 serving as a semiconductor substrate. The device layer 11 has been provided with the chip areas 2 in which the circuit element 21 has been formed. A surface of each of the chip areas 2 has been coated with the surface protective film 12.

The kerf area 3 has been provided between chip areas 2 adjacent to each other. In the kerf area 3, the dicing lines 4 that extend in the X direction and the Y direction are disposed. The dicing line 4 is an area that will disappear as a result of cutting using the cutting blade described later, and has a width that corresponds to a width of the cutting blade.

In cutting using the cutting blade, a material film can be peeled at a boundary between material films in the device layer 11, and therefore a crack that extends from a cut portion in parallel to the silicon substrate 10 can occur. In order to prevent the crack from extending to the chip area 2, a plurality of grooves 118 is formed in an area that overlaps the dicing line 4 in the present embodiment. The grooves 118 are formed prior to cutting using the cutting blade. The groove 118 is an example of a groove.

In forming the grooves 118, a not-illustrated laser beam machining device is used. The laser beam machining device includes a machining head 200. The machining head 200 is configured to be able to apply a plurality of laser beams 212 having abrasion effect.

As illustrated in FIG. 4B, the machining head 200 includes a single irradiation port 211 on a face that faces the device layer 11. In the example of FIG. 4B, seven laser beams are applied from the single irradiation port 211 toward the device layer 11. The seven laser beams 212 that have been applied from the single irradiation port 211 respectively form seven individual grooves 118. The seven respective laser beams 212 are simultaneously applied from the single irradiation port 211 so that the seven grooves 118 can be simultaneously formed.

For example, the machining head 200 moves above the semiconductor wafer 100 in the X direction and the Y direction along the dicing lines 4, as illustrated in FIG. 4A, while applying the seven respective laser beams 212 from the single irradiation port 211. This forms the seven grooves 118 (118-1 to 118-7) that extend along the dicing lines 4. The seven grooves 118 (118-1 to 118-7) are simultaneously formed on an identical plane in a width direction of the dicing lines 4.

However, the seven grooves 118 (118-1 to 118-7) do not necessarily need to be strictly simultaneously formed. There may be a small time difference in forming the individual grooves 118 according to a configuration of the machining head 200. Furthermore, the number of laser beams 212 that are applied from the single irradiation port 211 does not necessarily need to be seven.

Each of the seven grooves 118 (118-1 to 118-7) is formed to have a depth that does not reach the silicon substrate 10 from the upper face 11a of the device layer 11. The seven grooves 118 (118-1 to 118-7) have depths roughly equal to each other. However, the seven grooves 118 (118-1 to 118-7) may have depths different from each other. Each of the seven grooves 118 (118-1 to 118-7) are formed in a tapered shape having an opening width decreasing downward from the upper face 11a of the device layer 11. Here, it is assumed that respective distances in the Z direction from bottoms of the seven grooves 118 (118-1 to 118-7) to a surface of the silicon substrate 10 are H1 to H7. In this case, in a case where a variation in H1 to H7 is within 20% of the thickness of the device layer 11, and is small, it may be said that the seven grooves 118 (118-1 to 118-7) have been formed to have a roughly equal depth. For example, in a case where the device layer 11 has a thickness of 5 μm, and in a case where the seven grooves 118 (118-1 to 118-7) have been formed to have a roughly equal depth, a difference between a smallest value (a case where a corresponding groove 118 is deep) and a greatest value (a case where a corresponding groove 118 is shallow) of H1 to H7 is within 1 μm. Furthermore, the roughly equal depth may be within 10%.

The grooves 118 (118-1 to 118-7), as described above, are formed, and therefore a protrusion 119 that extends in the Z direction is formed between grooves 118 adjacent to each other. Six protrusions 119 (119-1 to 119-6) that are disposed to alternate with the seven grooves 118 (118-1 to 118-7) have been formed in an inverted tapered shape having a width increasing downward.

The seven respective grooves 118 are formed to have an interval P from an adjacent groove 118 in accordance with an interval of disposition of seven irradiation ports 211. For example, the seven grooves 118 have an equal interval P between each other. The interval P is also a width of the protrusion 119. The interval P is, for example, 20 μm or less. Note that it is more preferable that the interval P be small. This is because a decrease in the interval P enables the protrusion 119 to be easily broken by the cutting blade.

However, the seven grooves 118 do not necessarily need to have an equal interval P between each other. For example, the seven grooves 118 may be formed to have intervals P different from each other. In this case, it is sufficient if an interval P between grooves 118 closest to each other from among the seven grooves 118 is 20 μm or less.

Furthermore, each of the seven grooves 118 is formed in such a way that the interval P is smaller than the width of the dicing line 4. By doing this, at least one or more grooves 118 or protrusions 119 can be disposed inside the dicing line 4. For example, in FIG. 4B, the grooves 118-3 to 118-5 and the protrusions 119-2 to 119-5 are disposed inside the dicing line 4.

Furthermore, the seven respective grooves 118 are formed in such a way that an interval D between the groove 118-1 and the groove 118-7 that are located at both ends is greater than the width of the dicing line 4. By doing this, at least some of the seven grooves 118 and the six protrusions 119 can be disposed outside the dicing line 4. For example, in FIG. 4B, the groove 118-1 and the protrusion 119-1 are disposed on one outer side of the dicing line 4, and the protrusion 119-6 and the groove 118-7 are disposed on another outer side.

Next, as illustrated in FIGS. 5A and 5B, a cutting blade 300 is aligned with a position that overlaps the dicing line 4, and cuts the device layer 11 from an upper side toward a lower side. Stated another way, the grooves 118-3 to 118-5 and the protrusions 119-2 to 119-5 that are disposed inside the dicing line 4, and the device layer 11 that is disposed below these grooves and protrusions are cut.

Next to cutting the device layer 11, the silicon substrate 10 located in a position that overlaps the dicing line 4 is cut up to a predetermined depth.

As a result of the processing described above, the device layer 11 and a portion of the silicon substrate 10 that are located in a position that overlaps the dicing line 4 are removed. At this time, as illustrated in FIG. 5B, the protrusion 119-6 that is disposed outside the dicing line 4 is broken. However, the protrusion 119-6 does not necessarily need to be broken.

A width L of the cutting blade 300 is roughly the same as the width of the dicing line 4. Stated another way, as illustrated in FIG. 5A, the interval P between grooves 118 adjacent to each other is smaller than the width L of the cutting blade 300, and the interval D between the groove 118-1 and the groove 118-7 is greater than the width L of the cutting blade 300. The width L of the cutting blade 300 is, for example, greater than 20 μm, and less than or equal to 40 μm. However, the width L of the cutting blade 300 may be smaller than or equal to the width of the dicing line 4.

Next, as illustrated in FIG. 6A, the silicon substrate 10 is polished from a side of a lower face 10b by using, for example, the chemical mechanical polishing (CMP) method. The lower face 10b opposite to the upper face 10a. On the upper face 10a of the silicon substrate 10, a groove 103 has been formed as a result of the processing of FIG. 5B. The groove 103 includes a bottom face 103b.

As illustrated in FIG. 6B, by reducing the thickness of the silicon substrate 10 from a negative-direction side of the Z axis, the bottom face 103b of the groove 103 is opened, and an opening 103c is formed. This causes the chip areas 2 to be separated from each other. The manufacturing of the semiconductor device has terminated above.

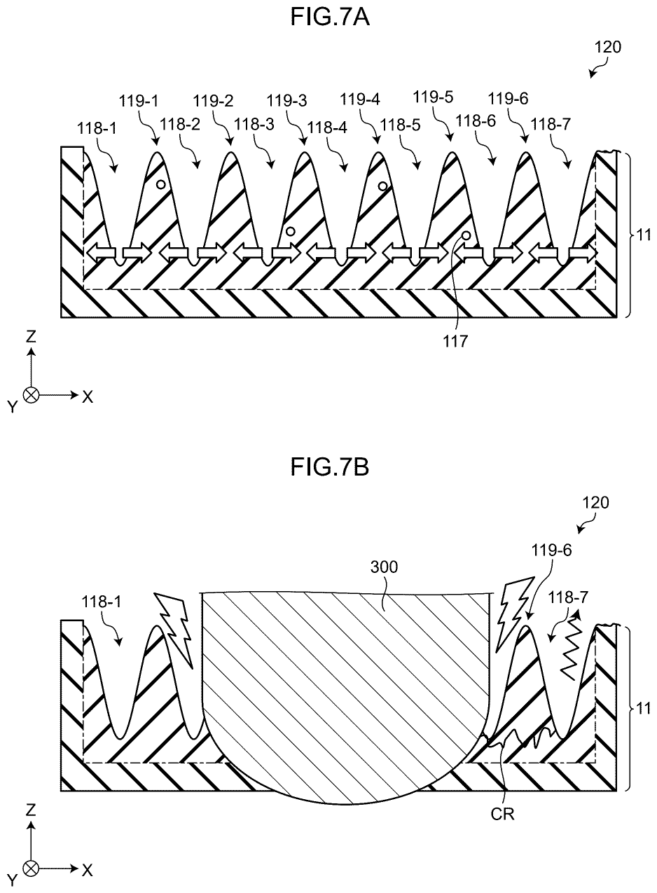

Here, a reason why the formation of the plurality of grooves 118 prevents a crack from extending to the chip areas 2 will be described with reference to FIGS. 7A and 7B.

FIGS. 7A and 7B are diagrams explaining the extension of a crack CR in a process of manufacturing the semiconductor device according to the embodiment. More specifically, FIGS. 7A and 7B are enlarged cross-sectional views of the kerf area 3 of the semiconductor wafer 100.

As illustrated in FIG. 7A, in the kerf area 3, the seven grooves 118 and the six protrusions 119 have been alternately formed by performing, for example, the processing of FIGS. 4A and 4B. In an area where the grooves 118 and the protrusions 119 described above have been formed, an affected layer called a heat-affected zone (HAZ) has been formed. The affected layer is a layer in which the device layer 11 has been affected due to an influence of heat or the like of the laser beams 212.

The affected layer has been formed over the entirety of the area of formation of the seven grooves 118 and the six protrusions 119. Specifically, the affected layer has been formed in the XY directions from the groove 118-1 to the groove 118-7. Furthermore, the affected layer has been formed from upper ends of the protrusions 119 to a depth position lower than lower ends of the grooves 118. Hereinafter, an area where such an affected layer has been formed is referred to as an “embrittled area 120” in some cases.

The embrittled area 120 is more vulnerable than the device layer 11 around the embrittled area 120. Furthermore, compressive stress has been generated inside the embrittled area 120. Therefore, the embrittled area 120 can be easily broken due to stress applied to the periphery. The hole 117 is formed in some cases.

Furthermore, as described above, the seven grooves 118 are simultaneously formed on an identical plane in the width direction of the dicing line 4. Therefore, inside the protrusions 119, compressive stress caused by the grooves 118 formed on both sides has been generated, as indicated with arrows in FIG. 7A. Therefore, the protrusions 119 can be easily broken along the upper face 10a (see FIG. 5A or the like) of the silicon substrate 10 due to stress applied to the periphery.

As illustrated in FIG. 7B, when the crack CR with a portion cut by the cutting blade 300 as a starting point has been generated, the crack CR extends along the silicon substrate 10 (see FIG. 5A or the like) over the embrittled area 120, and reaches the protrusion 119-6 that has been formed outside the dicing line 4. The crack CR that has reached the protrusion 119-6 enters from one side of the protrusion 119-6, and extends to another side. This causes the protrusion 119-6 to be broken in the XY directions. An upper portion of the protrusion 119-6 that has been broken in the XY directions is released in a positive direction of the Z axis. This guides the crack CR to a positive-direction side of the Z axis. As a result of this, the crack CR does not extend to the chip area 2.

As described above, the plurality of grooves 118 is formed in a position that overlaps the dicing line 4 so that the embrittled area 120 is formed. The crack CR only extends inside the embrittled area 120 along the upper face 10a (see FIG. 5A or the like) of the silicon substrate 10, and therefore the crack CR is prevented from extending to the chip areas 2.

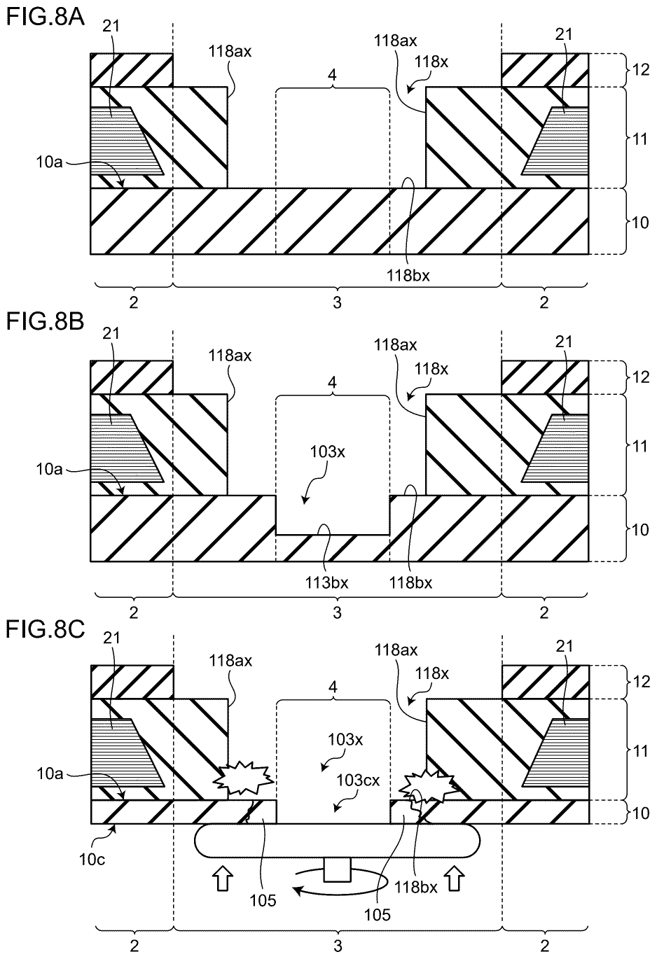

FIGS. 8A to 8C are diagrams explaining a semiconductor device manufacturing method in a comparative example.

As illustrated in FIG. 8A, in the semiconductor device manufacturing method in the comparative example, a single groove 118x having a width that is greater than the width of the dicing line 4 is formed along the dicing line 4. The groove 118x is formed to have a depth that reaches the silicon substrate 10. The groove 118x is formed to include two side faces 118ax that face each other, and a bottom face 118bx. The bottom face 118bx is also the upper face 10a of the silicon substrate 10.

Next, as illustrated in FIG. 8B, a position that overlaps the dicing line 4 in the upper face 10a of the silicon substrate 10 is cut to form a groove 103x in the silicon substrate 10. The groove 103x is formed to include two side faces 103ax that face each other, and a bottom face 103bx. The groove 103x is formed inside the groove 118x.

Therefore, outside the groove 103x, a portion of the bottom face 118bx is exposed. Above the portion of the bottom face 118bx that is exposed outside the groove 103x, the device layer 11 has not been formed.

Next, as illustrated in FIG. 8C, the silicon substrate 10 is polished from the negative-direction side of the Z axis, by using, for example, the CMP method. The thickness of the silicon substrate 10 is reduced from the negative-direction side of the Z axis so that a lower face 10c is formed, and an opening 103cx in which the bottom face 103bx of the groove 103x is open is also formed in the lower face 10c.

On both sides of the opening 103cx, eaves 105 that protrude from sides of the side faces 118ax of the groove 118x toward the opening 103cx are formed. The two eaves 105 face each other with the opening 103cx interposed therebetween. Upper faces of the eaves 105 correspond to a portion of the bottom face 118bx outside the groove 103x.

On the upper faces of the eaves 105, the device layer 11 has not been formed. Therefore, if the thickness of the silicon substrate 10 is further reduced by performing polishing that follows, it becomes difficult to make the eaves 105 have enough strength to be resistant to the impact of polishing. For example, in a case where the thickness of the silicon substrate 10 has been reduced to a requested thickness, there is a possibility that the eaves 105 will be broken due to the impact of polishing.

From the reason described above, in the semiconductor device manufacturing method in the comparative example, it is difficult to reduce the thickness of the silicon substrate 10 to a requested thickness in some cases. Stated another way, in the semiconductor device manufacturing method in the comparative example, it is difficult to reduce the semiconductor device in thickness.

Furthermore, as a result of highly stacking of semiconductor devices, the thickness of the device layer 11 tends to increase. Therefore, in the semiconductor device manufacturing method in the comparative example, in order to form the groove 118x having a depth that reaches the silicon substrate 10, laser beams need to be applied plural times. Therefore, in some cases, the productivity of semiconductor devices deteriorates, for example, such that the time of processing is extended.

Furthermore, in some cases, the groove 118x is formed in a tapered shape having an opening width decreasing downward due to characteristics of the laser beams. Therefore, as a result of an increase in thickness of the device layer 11, the opening width of the lower portion of the groove 118x becomes smaller than an opening width that enables the cutting blade 300 to perform cutting in some cases. This results in a limitation on an applicable cutting blade 300 in some cases.

### Overview

In the semiconductor device manufacturing method according to the present embodiment, the laser beams 212 are applied along the dicing lines 4 of the kerf area 3 so that the plurality of grooves 118 having a depth that does not reach the silicon substrate 10 is formed. The interval P between grooves 118 closest to each other from among the plurality of grooves 118 is smaller than the width L of the cutting blade 300, and the interval D between grooves 118 located on both ends from among the plurality of grooves 118 is greater than the width of the cutting blade 300.

As described above, by forming the plurality of grooves 118 along the dicing lines 4 by using the laser beams 212, the embrittled area 120 is formed in an area where the plurality of grooves 118 has been formed. By cutting the embrittled area 120, as described above, by using the cutting blade 300, the crack CR that has been generated with a cut portion as a starting point can be kept in the embrittled area 120. As a result of this, the crack CR can be prevented from extending to the chip areas 2.

Furthermore, in the semiconductor device manufacturing method according to the present embodiment, the plurality of grooves 118 is formed to have a depth that does not reach the silicon substrate 10. Therefore, the bottom face 118bx (see FIG. 8B) is not formed outside the groove 103. Therefore, the eaves 105 (see FIG. 8C) are not formed either. Thus, even in a case where the thickness of the silicon substrate 10 is further reduced by performing polishing that follows, the periphery of the opening 103c can have enough strength to be resistant to the impact of polishing. This enables the semiconductor device 1 to decrease in thickness to a requested thickness.

Furthermore, the plurality of grooves 118 is formed to have a depth that does not reach the silicon substrate 10, and this can reduce the number of times of irradiation with the laser beams 212. Therefore, the time of processing can be reduced, and this enables improvements in productivity.

Moreover, the plurality of grooves 118 is formed to have a depth that does not reach the silicon substrate 10, and this can prevent the opening width of the grooves 118 from decreasing. Therefore, the number of applicable cutting blades 300 can be increased.

While certain embodiments have been described, these embodiments have been presented by way of example only, and are not intended to limit the scope of the inventions. Indeed, the novel devices and methods described herein may be embodied in a variety of other forms; furthermore, various omissions, substitutions and changes in the form of the embodiments described herein may be made without departing from the spirit of the inventions. The accompanying claims and their equivalents are intended to cover such forms or modification as would fall within the scope and spirit of the inventions.

What is claimed is:

1. A semiconductor device manufacturing method comprising:
a first process of irradiating a device layer formed on a semiconductor substrate with a laser beam having abrasion effect along a dicing line of a semiconductor wafer to form a plurality of grooves having a depth that does not reach the semiconductor substrate in the device layer, the semiconductor wafer including chip areas that include circuit elements, and a kerf area that surrounds the chip areas, the dicing line being located in the kerf area, and being to be cut in singulating the chip areas; and
a second process of cutting the dicing line in a thickness direction of the semiconductor wafer using a cutting blade to singulate the chip areas, wherein
an interval between grooves closest to each other from among the plurality of grooves formed in the first process is smaller than a width of the cutting blade, and an interval between grooves located at both ends from among the plurality of grooves is greater than the width of the cutting blade.

2. The semiconductor device manufacturing method according to claim 1, wherein
forming of the plurality of grooves in the first process includes
forming the plurality of grooves at equal intervals.

3. The semiconductor device manufacturing method according to claim 1, wherein
the interval between the grooves closest to each other from among the plurality of grooves is 20 μm or less.

4. The semiconductor device manufacturing method according to claim 3, wherein
the width of the cutting blade is 20 μm or more.

5. The semiconductor device manufacturing method according to claim 1, wherein
forming of the plurality of grooves in the first process includes
simultaneously forming the plurality of grooves.

6. The semiconductor device manufacturing method according to claim 1, wherein
a plurality of laser beams including the laser beam are
individually applied from a single irradiation port provided in a machining head, and
forming of the plurality of grooves in the first process includes
forming individual grooves of the plurality of grooves by the plurality of laser beams that has been individually applied from the single irradiation port.

7. The semiconductor device manufacturing method according to claim 1, wherein
singulating of the chip areas in the second process includes:
forming a groove having a predetermined depth in the semiconductor wafer using the cutting blade; and
polishing a face opposite to a face on which the groove is formed in the semiconductor wafer until the groove is made open to singulate the chip areas.

8. The semiconductor device manufacturing method according to claim 1, wherein
the device layer includes:
a stacked body in which a plurality of conductive layers are stacked while being separated from each other individually; and
a pillar that extends in a stacking direction of the stacked body in the stacked body, a memory cell being formed in each of portions where the pillar crosses the plurality of conductive layers.

9. The semiconductor device manufacturing method according to claim 1, wherein
forming of the plurality of grooves in the first process includes
forming the plurality of grooves at an equal depth.

10. The semiconductor device manufacturing method according to claim 1, wherein
forming of the plurality of grooves in the first process includes
forming each of the plurality of grooves in a tapered shape having an opening width decreasing downward from an upper face of the device layer.

11. The semiconductor device manufacturing method according to claim 10, wherein
the forming of the plurality of grooves in the first process includes
forming a protrusion having an inverted tapered shape between grooves adjacent to each other from among the plurality of grooves, and
singulating of the chip areas in the second process includes
breaking the protrusion that is disposed outside the dicing line.

12. A semiconductor device comprising:
a device layer that is formed on a semiconductor substrate; and
a circuit element that is provided in the device layer, wherein
in an outer periphery of the device layer, a molten layer in which a surface of the device layer having been molten is formed.

13. The semiconductor device according to claim 12, wherein
compressive stress is generated at least either inside the molten layer or near the molten layer in the outer periphery of the device layer.

14. The semiconductor device according to claim 12, wherein
in the outer periphery of the device layer, at least either one or more grooves or one or more inclined faces are formed, the one or more grooves and the one or more inclined faces extending in an outer peripheral direction of the semiconductor substrate, and
the molten layer is formed on surfaces of either the one or more grooves or the one or more inclined faces.

15. The semiconductor device according to claim 12, wherein
the circuit element of the device layer includes:
a stacked body in which a plurality of conductive layers are stacked while being separated from each other individually; and
a pillar that extends in a stacking direction of the stacked body in the stacked body, a memory cell being formed in each of portions where the pillar crosses the plurality of conductive layers.

16. The semiconductor device according to claim 12, wherein
a hole is formed at least either inside the molten layer or near the molten layer in the outer periphery of the device layer.
